(19) United States
(12) Patent Application Publication
(10) Pub. No.: US 2010/0200968 A1
(43) Pub. Date: Aug. 12, 2010

(54) MICROWAVE CIRCUIT ASSEMBLY

(75) Inventors: GEORGE J. PURDEN, WESTLAKE VILLAGE, CA (US); MATTHEW R. WALSH, SHARPSVILLE, IN (US); FRANZ JOSEF SCHMUECKLE, KOENIGS WUSTERHAUSEN (DE)

Correspondence Address: DELPHI TECHNOLOGIES, INC;LEGAL STAFF - M/C 483-400-402, 5725 DELPHI DRIVE, PO BOX 5052, TROY, MI, 48007, US

(73) Assignee: DELPHI TECHNOLOGIES, INC., TROY, MI (US)

(21) Appl. No.: 12/704,613

(22) Filed: Feb. 12, 2010

Related U.S. Application Data
(60) Provisional application No. 61/151,891, filed on Feb. 12, 2009.

(51) Int. Cl. H01L 23/498

(52) U.S. Cl. 257/664; 257/728; 257/734; 257/E23.06

(57) ABSTRACT

A microwave circuit assembly including a flip-chip attachable integrated circuit die attached to a substrate by an interconnect device. The integrated circuit die and the substrate have microstrip transmission lines that are electrically coupled through the interconnect device. The interconnect device forms a transmission line configured to electrically couple the microstrip transmission line on the substrate to the microstrip transmission line on the integrated circuit die The interconnect device includes stubs to enhance the ground elements of the interconnect device transmission line and provide a microwave short for the integrated circuit die.

### CROSS-REFERENCE TO RELATED APPLICATION

This application claims the benefit under 35 U.S.C. §119(e) of U.S. Provisional Patent Application No. 61/151,891, filed Feb. 12, 2009, the entire disclosure of which is hereby incorporated herein by reference.

### TECHNICAL FIELD OF INVENTION

The invention generally relates to microwave circuit assemblies, and more particularly relates to providing an interconnect device to electrically couple the characteristic impedance of a flip-chip attached microwave integrated circuit die to the characteristic impedance of a substrate.

### BACKGROUND OF INVENTION

It is known to directly attach a gallium arsenide (GaAs) microwave integrated circuit die with the active side down to a substrate or circuit board. Such an attachment method, commonly known as flip-chip, uses solder balls to both mechanically attach the die to the substrate and make electrical connections. However, the initial performance of the flip-chip GaAs microwave die was restricted due to inductance from long vias required for ground connections to the backside of the GaAs microwave die. Consequently, coplanar waveguide (CPW) circuits comprising a coplanar arrangement of a signal path between two ground planes were developed to avoid the inductive ground connections and increase the operating frequency of the flip-chip GaAs microwave die.

Subsequently, silicon (Si) microwave integrated circuit die were developed that have microwave frequency performance competitive with GaAs at significantly lower die cost. Further development increased the operating frequencies of the Si die. However, the CPW circuits at these increased operating frequencies had spurious modes that lost power and degraded isolation. Air bridges may be used to prevent mode conversion, but are expensive to implement and their effectiveness is limited. Furthermore, CPW circuits had increased loss due to current concentration at the edges of the thin strips.

### SUMMARY OF THE INVENTION

In accordance with one embodiment of this invention, a microwave circuit assembly is provided. The microwave circuit assembly comprises an integrated circuit die, a substrate, and an interconnect device. The integrated circuit die is suitable for operation at microwave frequencies. The integrated circuit die has a first connection pad. The integrated circuit die also has a first microstrip transmission line configured to exhibit a first characteristic impedance. The substrate comprises a second connection pad. The substrate also comprises a second microstrip transmission line configured to exhibit a second characteristic impedance. The interconnect device is configured to attach the integrated circuit die to the substrate such that the first connection pad faces the second connection pad. The interconnect device is also configured to form a transmission line effective to electrically couple the first characteristic impedance to the second characteristic impedance.

In another embodiment of the present invention, a microwave circuit assembly is provided. The microwave circuit assembly comprises an integrated circuit die, a substrate, and an interconnect device. The integrated circuit die is suitable for operation at microwave frequencies. The integrated circuit die has an active side comprising a first connection pad suitable for flip-chip attachment and a first microstrip transmission line configured to exhibit a first characteristic impedance. The substrate comprises a second connection pad suitable for flip-chip attachment and a second microstrip transmission line configured to exhibit a second characteristic impedance. The interconnect device is configured to flip-chip attach the integrated circuit die to the substrate such that the first connection pad faces the second connection pad. The interconnect device is also configured to form a transmission line having a third characteristic impedance effective to electrically couple the first characteristic impedance to the second characteristic impedance.

Further features and advantages of the invention will appear more clearly on a reading of the following detail description of the preferred embodiment of the invention, which is given by way of non-limiting example only and with reference to the accompanying drawings.

### BRIEF DESCRIPTION OF DRAWINGS

The present invention will now be described, by way of example with reference to the accompanying drawings, in which:

FIG. 1 is a perspective view of a microwave circuit assembly in accordance with one embodiment;

FIG. 2 is a cut-away side view of the microwave circuit assembly shown FIG. 1 in accordance with one embodiment;

FIG. 3 is a close-up perspective view of part of the microwave circuit assembly shown in FIG. 1 in accordance with one embodiment; and

FIG. 4 is a close-up cut-away view of part of the microwave circuit assembly shown in FIG. 1 in accordance with one embodiment.

### DETAILED DESCRIPTION OF INVENTION

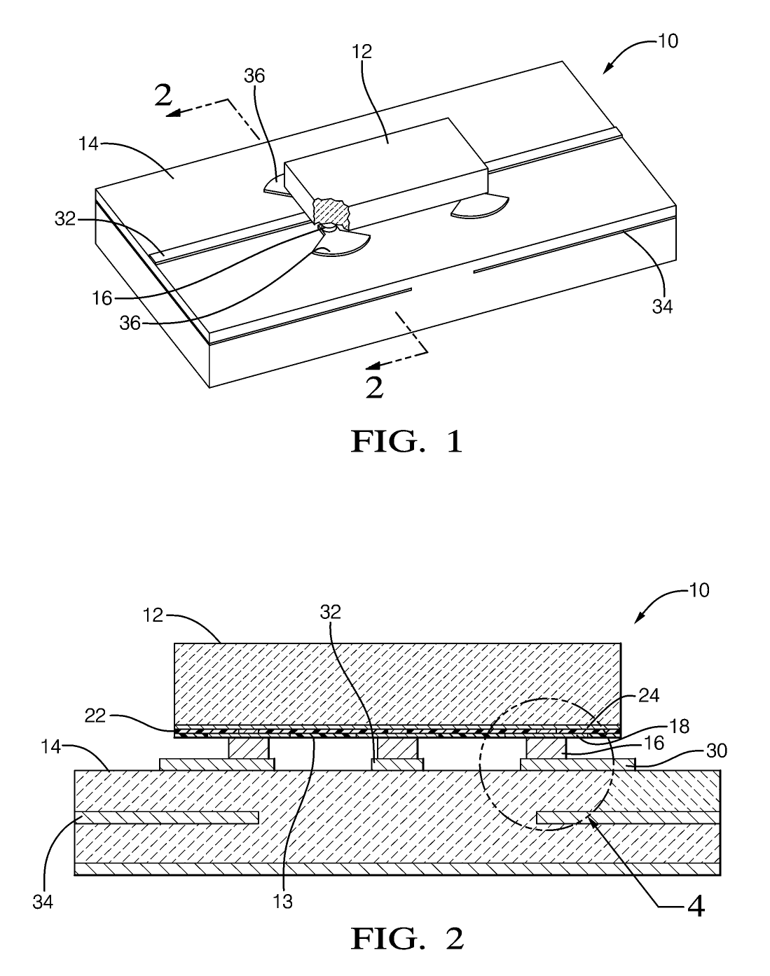

In accordance with an embodiment of the invention, FIGS. 1 and 2 illustrate a microwave circuit assembly 10 suitable for use with signals having frequencies in the range of, but not limited to, about 300 MHz (0.3 GHz) to about 300 GHz. Being able to operate at microwave frequencies may be useful for applications such as radar systems, communications systems, and radio devices. FIGS. 1 and 2 illustrate the microwave circuit assembly 10 having an integrated circuit die 12 attached to a substrate 14 by way of an interconnect device 16. It should be understood that the substrate 14 as illustrated may be only a portion of a larger substrate such that the microwave circuit assembly 10 may also have other electrical components not shown such as resistors, capacitors, or other integrated circuit devices.

The integrated circuit die 12 may be an arrangement of one or more transistors, an amplifier, a modulator, or other device suitable for use at microwave frequencies. The integrated circuit die 12 may have a first connection pad 18 formed of a material suitable for forming a secure attachment to the interconnect device 16. For example, a suitable material may be tinned nickel plating, silver plating, or gold plating. However, it is understood by those skilled in the art that the preferred material is generally selected based on the material used for the interconnect device 16. In one embodiment, the integrated circuit die 12 has an active side 13. As used herein the active side 13 is the side of the die where metal traces and structures such as transistors are formed. It is desirable to locate the first connection pad 18 and on the active side 13 so as to avoid two sided wafer processing during fabrication of the integrated circuit die 12, and avoid long vias through the body of the integrated circuit die that may exhibit objectionable inductance.

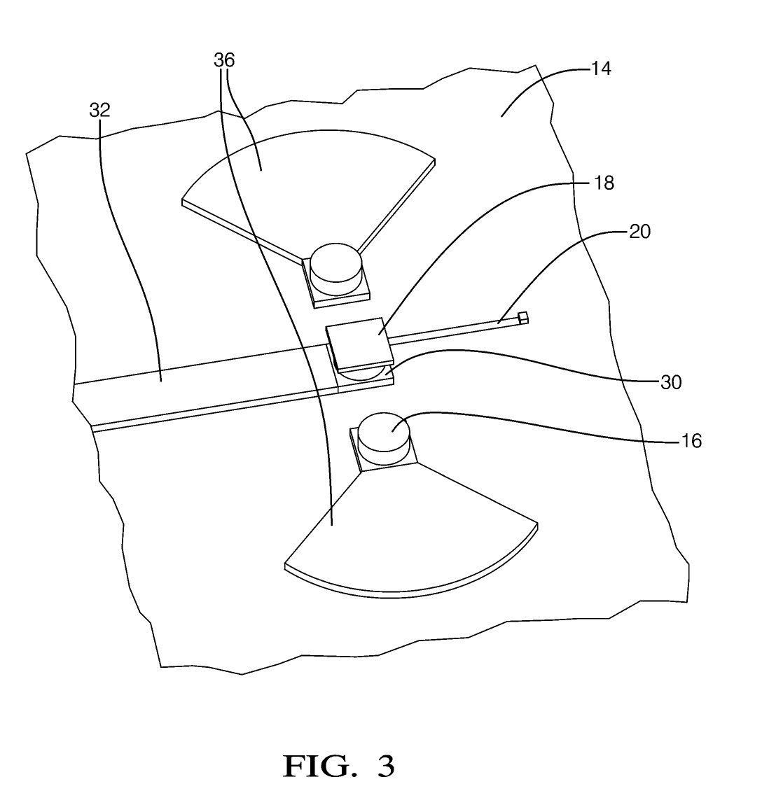

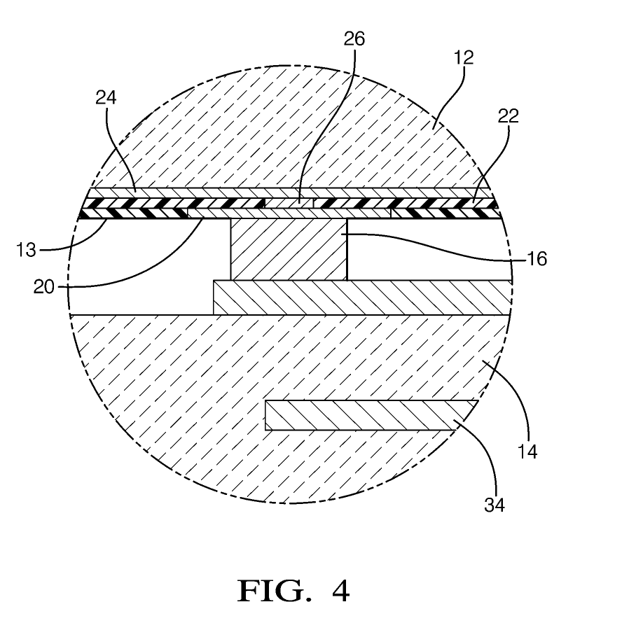

FIG. 3 illustrates a close-up view of FIG. 1 with the integrated circuit die 12 removed for illustration purposes, except for the first connection pad 18 and an integrated circuit microstrip 20 that is part of a first microstrip transmission line. As used herein, a microstrip transmission line is generally described as a flat conductor having a specific conductor width much greater than the thickness of the conductor overlying a ground plane and separated from the ground plane by an insulating dielectric layer by a specific distance. It is desirable for the first microstrip transmission line on the integrated circuit die 12 to use a thin passivation layer 22, as illustrated in FIG. 2, to insulate the integrated circuit microstrip 20 from an integrated circuit ground plane 24. By using a thin passivation layer on the same side of a die, as opposed to using the die as an insulating layer to a ground plane on the opposite or back side of the die, the width of the microstrip may be reduced. The integrated circuit microstrip is preferably formed on the surface metal layer of the integrated circuit die 12. The integrated circuit ground plane may be formed on a metal layer below the surface metal layer, preferably the metal layer immediately below the surface metal layer. In one embodiment, the first microstrip transmission line may be conveniently formed of thin film material as part of the integrated circuit fabrication process. Electrical connection from the surface metal layer of the integrated circuit die 12 to the integrated circuit ground plane may be by way of a ground via 26, as illustrated in FIG. 4

In one embodiment, the integrated circuit die is formed substantially of silicon. The arrangement of metal layers forming the first microstrip transmission line may be readily formed on silicon (Si) based integrated circuits, and is fundamentally different from the ground plane arrangement typically found on gallium arsenide (GaAs) based integrated circuits, where a layer of metal on the backside surface opposite the active side provides the ground plane, and the GaAs die is use as the insulator. Connections to this backside ground plane are made using long vias reaching through the thickness of the GaAs die that lead to undesirably high inductance in the ground plane connection. The reduced insulator thickness of the passivation layer 22 provides for a low inductance connection from the substrate 14 to the ground plane 24 via the interconnect device 16, thereby minimizing losses and maximizing bandwidth. As such, the configuration of the first microstrip transmission line may exhibit a first characteristic impedance. Microstrip transmission lines provide flexible routing, reduced loss, and reduced coupling to spurious modes, as compared to coplanar waveguide (CPW) circuits.

The width of a microstrip, the thickness of an insulating layer, and the dielectric constant of the insulating layer influence the characteristic impedance of a microstrip transmission line. By way of a non-limiting example, a typical integrated circuit may have the integrated circuit microstrip 20 and the integrated circuit ground plane 24 separated by an insulating layer having a thickness of about 9.2 micrometers (μm), the integrated circuit microstrip 20 having a width of about 16 micrometers, and the insulating layer having a dielectric constant relative to air of about 4.1. With this arrangement, the first characteristic impedance may be calculated using equations known to those skilled in the art to be about 50 Ohms.

In one embodiment, the substrate 14 formed using a known low temperature co-fired ceramic (LTCC) multi-layer arrangement of alumina insulators and thick film ink conductors. Alternately, the substrate 14 may be formed in an alumina substrate with alternating layers of thick film conductors and dielectric or insulating layers, or may be formed using a known FR-4 type circuit board assembly. The substrate 14 includes a second connection pad 30 adapted to form an attachment to the interconnect device 16. The substrate 14 also includes a second microstrip transmission line formed by an arrangement of a substrate microstrip 32 overlying a substrate ground plane 34. As such, the second microstrip transmission line may exhibit a second characteristic impedance. While not explicitly shown, it should be appreciated that there may be other layers in the substrate 14 below the substrate ground plane for routing power and other signals to and from the integrated circuit die 12.

As discussed above, the width of a microstrip, the thickness of an insulating layer, and the dielectric constant of the insulating layer influence the characteristic impedance of a microstrip transmission line. By way of a non-limiting example, the arrangement of the substrate 14 may correspond to a typical LTCC circuit board where the substrate microstrip 32 and the substrate ground plane 34 are separated by about 100 micrometers (μm), the substrate microstrip 32 has a width of about 100 micrometers, and the dielectric constant of the insulating layer relative to air is about 9.7. With this arrangement, the second characteristic impedance is about 50 Ohms.

The interconnect device 16 is adapted to attach the integrated circuit die 12 to the substrate 14 such that the first connection pad 18 faces the second connection pad 30. Such an arrangement is commonly called a flip-chip attachment. In one embodiment the interconnect device includes a solder ball. One way to assemble such an arrangement is to apply liquid solder flux to the integrated circuit die 12 and the substrate 14 to temporarily hold a solder ball in place, and then apply sufficient heat to melt the solder ball and thereby form a solder joint between the solder ball and the first and second connection pads 18 and 30. Alternately, the interconnect device may be formed of electrically conductive epoxy using known materials and processes.

The interconnect device 16 may be configured to form a transmission line that exhibits a third characteristic impedance to electrically couple or match the first characteristic impedance to the second characteristic impedance. In one embodiment, the interconnect device 16 may include an attachment device either along side an attachment device coupling the first microstrip 20 to the second microstrip 32, or two attachment devices on opposite sides of the attachment device coupling the first microstrip 20 to the second microstrip 32 as illustrated in FIG. 1-2. The attachment device may include a solder ball or a portion of conductive epoxy. Such an arrangement may provide interconnect device grounds on opposite sides of the signal path coupling the first microstrip 20 and the second microstrip 32 such that a three-wire transmission line is formed having transmission characteristics similar to a coplanar waveguide (CPW). By way of an example, if the pads are 100 micrometers square separated by a 100micrometer gap, the characteristic impedance of the transmission line is about 50 Ohms.

In another embodiment the interconnect device 16 may also include a microwave short circuit or stub 36 arranged to provide a ground element for the transmission line formed by the interconnect device. FIG. 1-2 illustrates one non-limiting example of the stub 36 in the shape of a radial stub. It will be appreciated by those skilled it the art that there are a variety of shapes of stubs that would provide effective microwave grounding for the transmission line formed by the interconnect device 16. It will also be appreciated that by forming the stub 36 on the substrate 14, the interconnect device grounds present a microwave short circuit over a bandwidth effective to electrically couple the first characteristic impedance to the second characteristic impedance.

In one embodiment of the microwave circuit assembly 10, the first characteristic impedance, the second characteristic impedance, and the third characteristic impedance are substantially equal as suggested by the examples above. However if one of the characteristic impedances is not equal to the other two, or all three characteristic impedances are substantially unequal, then the microwave circuit assembly 10 may include one or more impedance structures to influence or compensate one or more of the characteristic impedances.

In one embodiment the integrated circuit die 12 includes an impedance structure formed by a structure of thin film configured to influence the first characteristic impedance. Examples of known impedance structures formed of thin film include, but are not limited to, a capacitor formed by overlaying layers of conductive thin film material separated by layers of dielectric material, or an inductor formed with a spiral arrangement of conductive thin film material. In one embodiment the substrate 14 includes an impedance structure configured to influence the second characteristic impedance. Examples of known impedance structures include, but are not limited to, a filter formed by an arrangement of conductor material to form a quarter wave transformer, or an inductor formed with a spiral arrangement of conductor material.

Accordingly, a microwave circuit assembly 10 is provided. The microwave circuit assembly 10 has a flip-chip attachable integrated circuit die 12 attached to a substrate 14. Both the integrated circuit die 12 and the substrate 14 have microstrip transmission lines electrically coupled through an interconnect device 16 forming a transmission line configured to electrically couple the microstrip transmission lines. Additionally, a novel termination structure that adds stubs 36 to ground elements of the interconnect device 16 transmission line provides a microwave short for the integrated circuit die 12 circuit that increases bandwidth.

The arrangement of the integrated circuit die 12, the substrate 14 and the interconnect device 16 transforms or matches signals between the first microstrip transmission line and the second microstrip transmission line. Testing has shown that a microwave circuit assembly 10 that has dimensions similar to those given in the examples above provides microwave circuit assemblies suitable for use around 77 GHz. Adding the stubs 36 further enhances the assembly to provide bandwidths greater than 25 GHz.

While this invention has been described in terms of the preferred embodiments thereof, it is not intended to be so limited, but rather only to the extent set forth in the claims that follow.

We claim:

1. A microwave circuit assembly comprising:
an integrated circuit die suitable for operation at microwave frequencies, said integrated circuit die having a first connection pad and a first microstrip transmission line configured to exhibit a first characteristic impedance;
a substrate comprising a second connection pad and a second microstrip transmission line configured to exhibit a second characteristic impedance; and
an interconnect device configured to attach the integrated circuit die to the substrate such that the first connection pad faces the second connection pad, and electrically couple the first characteristic impedance to the second characteristic impedance.

2. The assembly in accordance with claim 1, wherein the integrated circuit die is formed substantially of silicon.

3. The assembly in accordance with claim 1, wherein the integrated circuit die comprises an active side, and the first connection pad and the first microstrip transmission line are located on the active side.

4. The assembly in accordance with claim 1, wherein the first microstrip transmission line is formed of thin film material.

5. The assembly in accordance with claim 1, wherein the substrate is substantially formed of ceramic, and the second microstrip transmission line is formed of thick film material.

6. The assembly in accordance with claim 1, wherein the interconnect device is configured to form a transmission line that exhibits a third characteristic impedance effective to electrically couple the first characteristic impedance to the second characteristic impedance.

7. The assembly in accordance with claim 6, wherein the interconnect device further comprises a stub arranged to provide a ground element for the transmission line formed by the interconnect device.

8. The assembly in accordance with claim 6, wherein the interconnect device further comprises a pair of stubs arranged on opposite sides of the first and second microstrip transmission lines to provide a ground element for the transmission line formed by the interconnect device.

9. The assembly in accordance with claim 1, wherein the interconnect device comprises a solder ball.

10. The assembly in accordance with claim 1, wherein the first characteristic impedance, the second characteristic impedance, and the third characteristic impedance are substantially equal.

11. The assembly in accordance with claim 1, wherein the integrated circuit die further comprises an impedance structure formed by a structure of thin film configured to influence the first characteristic impedance.

12. The assembly in accordance with claim 1, wherein the substrate further comprises an impedance structure configured to influence the second characteristic impedance.

13. A microwave circuit assembly comprising:
an integrated circuit die suitable for operation at microwave frequencies, said integrated circuit die having an active side comprising a first connection pad suitable for flip-chip attachment and a first microstrip transmission line configured to exhibit a first characteristic impedance;
a substrate comprising a second connection pad suitable for flip-chip attachment and a second microstrip transmission line configured to exhibit a second characteristic impedance; and
an interconnect device configured to flip-chip attach the integrated circuit die to the substrate such that the first connection pad faces the second connection pad, and configured to form a transmission line having a third characteristic impedance effective to electrically couple the first characteristic impedance to the second characteristic impedance.

14. The assembly in accordance with claim 13, wherein the interconnect device further comprises a stub arranged to provide a ground element for the transmission line formed by the interconnect device.
